(19) United States
(12) Patent Application Publication
(10) Pub. No.: US 2023/0345627 A1
(43) Pub. Date: Oct. 26, 2023

(54) CIRCUIT BOARD ARCHITECTURE SUPPORTING MULTIPLE COMPONENT SUPPLIERS

(71) Applicant: Microsoft Technology Licensing, LLC, Redmond, WA (US)

(72) Inventors: Fatemeh ZOLFAGHAR, Redmond, WA (US); Rich Tat AN, Renton, WA (US); Bhret Robert GRAYDON, San Jose, CA (US)

(21) Appl. No.: 17/729,801

(22) Filed: Apr. 26, 2022

(51) Int. Cl. H05K 1/02

(52) U.S. Cl. CPC H05K 1/0262; H05K 2201/10045

(57) ABSTRACT

Techniques and systems for electronic circuit board design is provided herein. An example apparatus comprises an input structure that couples an input voltage node on a circuit board to input nodes of more than one voltage regulator circuit, wherein at least controller footprints differ among each of the more than one voltage regulator circuit. The apparatus further comprises a shared structure that couples switch nodes of the more than one voltage regulator circuit to a first terminal of an inductor footprint common to the more than one voltage regulator circuit, and an output structure that couples a second terminal of the inductor footprint to an output voltage node.

### BACKGROUND

Printed circuit boards are widely used across various types of computing and electronic devices. These circuit boards may be populated with various electrical components including integrated circuit components, active and passive components, and connectors. Typically, surface mount technology (SMT) components are employed that mount directly to a surface of a circuit board, although through-hole components are sometimes still encountered for larger components. The layout design for placement of these components on circuit boards can include consideration of the physical shape of components, proximity to functional circuit groups, the arrangement of component connections, pins, or leads, various signal and voltage requirements, the positioning of elements relative to power supply or ground connections, thermal dissipation, noise, signal integrity, and other considerations.

In computing systems, for example, integrated circuit devices can have various packaging and pinouts with voltage domains that correspond to particular power distribution subdivisions within the integrated circuit devices. The voltage domains are supplied by corresponding voltage regulator elements, typically positioned on an accompanying circuit board, sometimes referred to as a motherboard or mainboard. Common voltage regulator types include DC-DC switching regulators, able to reduce or increase a voltage level of an input voltage to produce a desired output voltage using high-speed switching of power transistor elements in combination with various passive components. Switching voltage regulators may employ controllers formed from integrated circuits that control switching of power transistors to produce the desired output voltages, along with inductor and capacitor elements acting as energy storage and filtering components. For low current applications, the controller and the transistors can be integrated into a common package. However, even in such scenarios, the arrangement of elements on the board, such as the controllers, inductors, capacitors, and other elements, can greatly impact the performance, thermal dissipation, tolerances, noise, and longevity associated with corresponding circuit components.

When a circuit board is initially designed, the associated circuit board layout is determined based on a selected electrical design. For example, an electrical designer typically includes a power supply suited to the various active or integrated circuit devices on the circuit board, then a layout specialist determines an arrangement for mounting and connecting those devices on a circuit board. Unfortunately, this configuration can be limited as the selected components are typically not interchangeable with other components. This can relevant during periods of supply chain shortages, or as various components are sunset or phased out of production from limited production lifecycles. This can lead to production delays, or expensive and cumbersome redesign of circuit boards along with associated production or manufacturing changes.

### OVERVIEW

Enhanced apparatuses, systems, and techniques are presented for electronic circuit board designs to mitigate component selection risks, such as those associated with interruptions in supply chains and component availability for circuit board components. Unpopulated circuit boards may be provisioned with designs and footprints for multiple alternate components, such as voltage regulators, which may share some common components, such as a shared switch node and voltage output plane having footprints for a shared inductor, thereby enabling provisioning of power to a voltage domain with any one of a plurality of different voltage regulator components.

In one example, an apparatus includes an input structure on a circuit board that couples an input voltage node to input nodes of more than one voltage regulator circuit, where at least controller footprints differ among each of the more than one voltage regulator circuit. A shared structure couples switch nodes of the more than one voltage regulator circuit to a first terminal of an inductor footprint common to the more than one voltage regulator circuit. An output structure couples a second terminal of the inductor footprint to an output voltage node.

In another example, a system includes a circuit board assembly that further includes a circuit board having an input structure that couples an input voltage node on the circuit board to input nodes of more than one voltage regulator circuit, where at least controller footprints differ among each of the more than one voltage regulator circuit. The system includes components unique to a first voltage regulator circuit populated onto the circuit board, and components unique to a second voltage regulator circuit not populated onto the circuit board. An input structure couples an input voltage node to input nodes of the first voltage regulator circuit and the second voltage regulator circuit. A shared structure couples switch nodes of the first and the second voltage regulator circuits to a first terminal of an inductor, such that the inductor is common to the more than one voltage regulator circuit. An output structure couples a second terminal of the inductor to an output voltage node. The circuit board assembly is configured to provide power to the output voltage node through the inductor when either one of the components unique to the first voltage regulator circuit and components unique to the second voltage regulator circuit are populated onto the circuit board.

In yet another example, a method includes forming an input structure on a circuit board that couples an input voltage node to input nodes of a first voltage regulator circuit and a second voltage regulator circuit, where at least controller footprints differ among the first and the second voltage regulator circuits. The method also includes forming a shared structure on the circuit board that couples switch nodes of the first and the second voltage regulator circuits to a first terminal of an inductor footprint common to the first and the second voltage regulator circuits. The method also includes forming an output structure on the circuit board that couples a second terminal of the inductor footprint to an output voltage node. The method also includes selectively populating the circuit board with either components unique to the first voltage regulator circuit or components unique to the second voltage regulator circuit, populating the circuit board with the inductor, and enabling the provision of power to the voltage output node by way of the selectively populated first voltage regulator circuit or second voltage regulator circuit.

This Overview is provided to introduce a selection of concepts in a simplified form that are further described below in the Detailed Description. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates a schematic representation of circuit board design in an implementation.

FIG. 2 illustrates a circuit board layout representation of circuit board design in an implementation.

FIG. 3 illustrates a circuit board layout representation of circuit board design in an implantation.

FIG. 4 illustrates example design and assembly operations in an implementation.

FIG. 5 illustrates an example computing system in an implementation.

### DETAILED DESCRIPTION

Enhanced apparatuses, systems, and techniques are presented for adaptable electronic circuit board designs to mitigate component selection risks, such as those associated with interruptions in supply chains and component availability for circuit board components. Unpopulated circuit boards may be provisioned with designs and footprints for multiple alternate configurations, such as controllers and associated circuitry for switching voltage regulators. These alternate configurations may share some common components, such as a shared switch node and voltage output plane having footprints for a shared inductor, thereby enabling provisioning of power to a voltage domain with any one of a plurality of different voltage regulator components. The multiple alternative component footprints may be positioned to connect to and function with shared components on the circuit board, such that the circuit board may be populated and function at a desired capacity, regardless of which of the alternative components is available during manufacturing of the circuit board assembly. The following description provides examples relating to provisioning an electronic circuit board to receive multiple alternate voltage regulator designs, although the discussion is not limited to only power supplies or voltage regulators.

Many computing systems employ high-performance integrated circuit devices, such as system-on-a-chip (SoC) devices, central processing units (CPUs), or graphics processing units (GPUs), as well as many peripheral components/devices and communication interfacing components. These various components receive power supplied by various power control and voltage regulator elements which alter a common input voltage level into individually-regulated domains, typically having lower output voltages than provided by the input. In one example, the power supplied to an integrated circuit device is often subdivided among voltage regulators into domains or rails each supplying power at a particular voltage level to a particular electrically-segregated voltage domain or voltage domain within the integrated circuit device. Thus, GPU cores, CPU cores, input/output portions, security cores, or various data/control cores of an integrated circuit device might have individually-dedicated voltage domains supplied using individually-dedicated power delivery networks (PDNs). Other components, such as interfacing elements, might provide power to peripheral devices and require separately regulated power supply components.

Power supply circuitry comprises circuit routing, circuit board power planes, capacitors, inductors, and power delivery components like regulators, power field effect transducers (FETs), diodes, integrated controllers, or other devices that establish the electrical pathways extending from supply voltages, through voltage regulators, and to the target devices. Power supply circuitry can also include connections on a circuit board for target integrated circuit devices, packaging/carrier pathways for the integrated circuit devices, and power distribution elements within the semiconductor and metallization structures of the integrated circuit device itself to deliver power to active circuit components. Designing an electronic circuit board that can employ different alternate voltage regulators includes accounting for electrical pathways from a shared voltage source, through alternate voltage regulators, and then through other shared components to provide power.

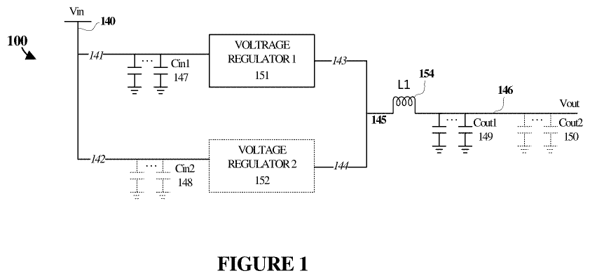

FIG. 1 shows an example circuit board design. FIG. 1 depicts a schematic diagram of a system 100 in accordance with certain examples of the present disclosure. Electrical connections between components may be referred to as nodes, and currents may be delivered through electrical connections, sometimes called voltage planes or voltage rails when placed/routed onto a circuit board. An unpopulated circuit board may be designed with planes and nodes based on where SMT components may be affixed later. System 100 thus includes a schematic diagram of components of a power supply configuration that is configured to convert a voltage level supplied at an input voltage source Vin 140 to an output voltage line Vout 146.

Vin 140 may include an input voltage source for a device, which may be regulated and reduced to a lower voltage appropriate for the power domain managed by the power supply configuration of system 100. Voltage from the Vin 140 may be provided to one or more input structures on a circuit board (e.g. voltage planes) via one or more input voltage nodes to input nodes of one or more voltage regulator circuits. In the depicted example, the system can accommodate two different voltage regulator circuit designs, voltage regulator 1 151 and voltage regulator 2 152. Power from Vin 140 may pass along path 141 to voltage regulator 1 151, where the path 141 may have corresponding one or more input capacitors (CM) 147. Similarly, power from Vin 140 may pass along path 142 to voltage regulator 2 152, where path 142 may have corresponding one or more input capacitors 148.

A switch node of voltage regulator 1 151 may couple at path 143 to a common switch node 145, and a switch node of voltage regulator 2 152 may couple at path 144 to the common switch node 145. For a buck or step-down voltage converter topology employed in this example, switch node 145 corresponds to a switching portion of a switching voltage regulator, where the output of one or more transistor devices produces an on-off waveform to reduce an input voltage into discrete portions of energy which are stored within a corresponding inductor element. These discrete portions of energy are then shaped by both the inductor element and output capacitance to produce a regulated output voltage at node 146 having a voltage ripple below a target amount. Similar concepts might be applied to other voltage converter topologies, but the shared node among parallel designs can vary.

Thus, the switch node of voltage regulator 1 151 and voltage regulator 2 152 may both be provided to a shared switch node, such as switch node 145. Inductor 154 spans from switching node 145 to a voltage out node Vout 146. Vout 146 may include one or more output capacitors, which can be determined based on designed performance of the associated voltage regulator. For example, Vout 146 may include a first set of one or more output capacitors (Cout 1) 149, and a second set of one or more output capacitors 150. In some examples, Cout1 149 may correspond to voltage regulator 1 151, and Cout 2 150 may correspond to voltage regulator 2 152. An output capacitor may “correspond to” a voltage regulator based on circuit board positioning of the capacitors relative to the positioning of the voltage regulators, as well as any design-specific selections of capacitance for a particular regulator.

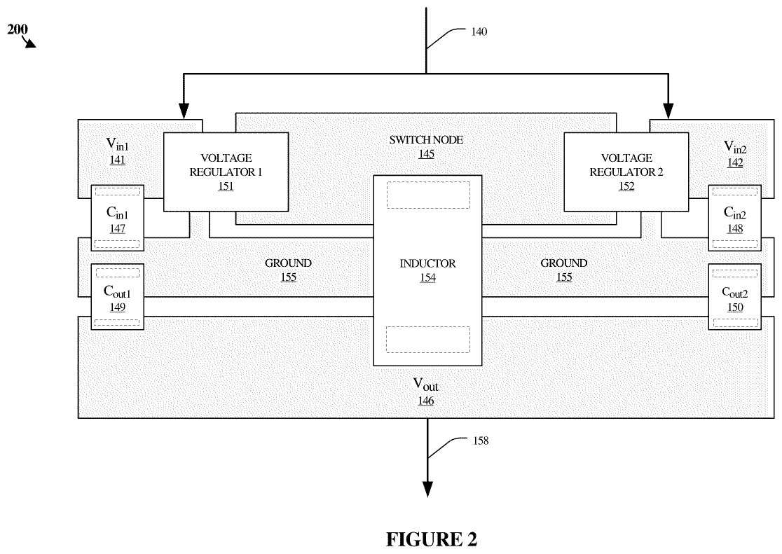

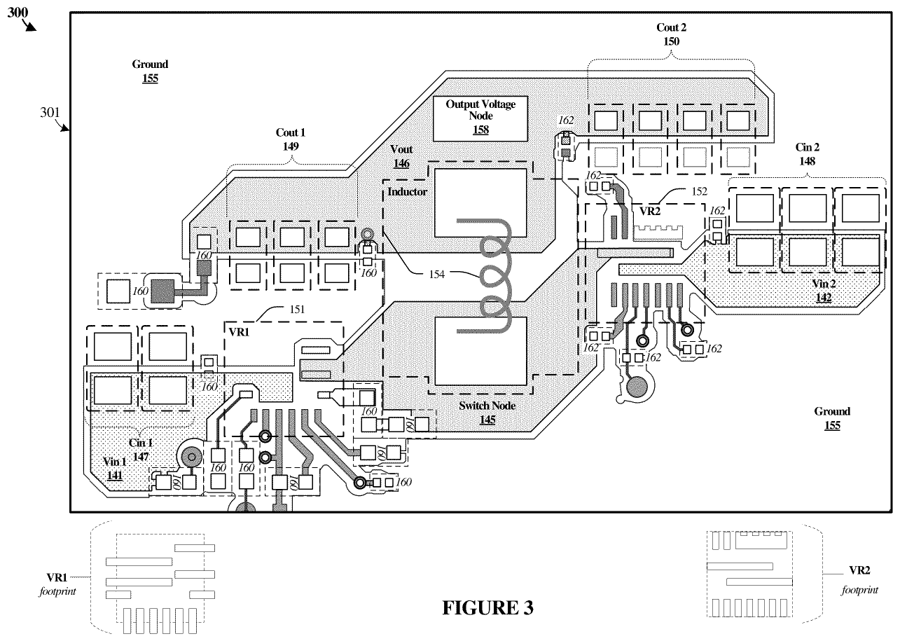

As density and power requirements of integrated circuitry has increased, supplying stable power across various operating conditions can be challenging. For example, transient response and stability of voltage rails supplying portions of target circuit can depend on the dynamic operation of the target circuit as well as the existence of parasitic inductive characteristics. Deploying capacitance to assist in transient response of voltage rails can mitigate these issues, such as by decreasing the influence of high frequency transient events (spikes or dips) by providing localized pools of charge closer to the affected circuitry and shunting noise of certain frequencies to ground. The effectiveness of capacitors in particular, and the entire regulator circuit in general, is often related to the capacitance values of the capacitors as well as an area defined by physical paths that electrical current takes when traveling to individual capacitors. The area inside this path or loop translates to inductance, and this inductance limits the frequencies over which the capacitor can be effective. Accordingly, the positioning of capacitors relative to voltage regulators can be a factor in stable and efficient functionality of a system. Example physical arrangements of the components of power supplies are depicted in FIGS. 2 and 3.

FIG. 2 depicts a simplified layout diagram of a system 200 including an electronic circuit board design, in accordance with certain examples of the present disclosure. System 200 includes components corresponding to those described in FIG. 1. In particular, FIG. 2 shows an example physical arrangement of components populated on corresponding mounting features of a circuit board. The components depicted in FIG. 2 may represent components populated on a circuit board, or may instead represent the footprints or intended placements of components that can be populated onto an unpopulated circuit board. Also, while features of elements in FIG. 2 correspond numerically to electrical components of FIG. 1, it should be understood that other configurations of electrical components are possible.

Vin 140 may provide an input voltage to electrical node and routing structure Vin1 141, and electrical node and routing structure Vin2 142. Vin1 141 and Vin2 142 may include voltage planes or rails that connect Vin 140 to input nodes of voltage regulator 1 151 and voltage regulator 2 152, respectively. Vin 141 may include a set of one or more input capacitors Cin1 147, proximate to voltage regulator 1 151, that connect between Vin1 141 and ground plane 155. Cin1 147 may be situated to reduce a current return path to voltage regulator 1 151 to a threshold distance. The threshold distance may be set to achieve a desired parasitic inductance limit or power stability within system 200 by keeping a current return distance between Cin1 147 and voltage regulator 151 low. Similarly, Vin 142 may include a set of one or more input capacitors Cin2 148, proximate to voltage regulator 2 152, that connect to ground plane 155. The capacitors Cin2 148 may be situated to reduce a current return path to voltage regulator 1 152 to a threshold distance.

Switch nodes of voltage regulator 1 and voltage regulator 2 may both connect to a shared routing structure or plane, labeled switch node 145. Switch node 145 may connect voltage regulators 151, 152 to a first terminal of inductor 154. A second terminal of inductor 154 may connect to a voltage output plane Vout 146, which may have an output voltage node 158 connecting system 200 to components within the power domain managed by system 200. Vout 146 may include one or more sets of output capacitors (Cout 1, 2) connecting between Vout 146 and ground plane 155, with each set including one or more capacitors. Vout 146 may include a single set of output capacitors common to both voltage regulators, or may include a set corresponding specifically to each voltage regulator. For example, a first set, Cout1 149, may correspond to voltage regulator 1 151, while a second set, Cout2 150, may correspond to voltage regulator 2 152. A positioning or layout for the one or more sets of Cout capacitors may be selected to position the capacitors proximate to the voltage regulators, situated to reduce current return paths to the voltage regulator circuits to a threshold distance. For example, a single set of output capacitors might be positioned to be within a threshold distance of both voltage regulator placements. Alternately, system 200 may include multiple sets of output capacitors (such as shown in FIG. 2), with each corresponding to and being within the threshold distance of one or more voltage regulator placements. When discussing placement of capacitors (CM and Cout), relative to a voltage regulator, the positioning may be relative to a controller circuit or integrated circuit package that forms a voltage regulator, or any other appropriate element of or associated with the voltage controller.

As can be seen in FIG. 2, two independent voltage regulators 151, 152 are included in placement/routing of system 200. These two voltage regulators share a common switch node (145) and common inductor (154), as well as common input and output electrical nodes. At any given time, only one selected voltage regulator and affected components will normally be populated onto an associated circuit board. For example, when voltage regulator 151 is selected for population, then components 147, 149, and 154 will also be populated. Alternatively, when voltage regulator 152 is selected for population, then components 148, 150, and 154 will also be populated. In both cases, inductor 154 will be populated, although the exact component used for inductor 154 may vary between each instance of voltage regulator. Thus, when one regulator is selected for population on the circuit board, the other regulator and affected components are not populated, and vice versa. The actual components selected for population can be controlled by various automated manufacturing equipment that can select which components are presently available for placement onto the associated circuit board. Thus, component availability can be deduced on-the-fly without affecting circuit performance and without changing the circuit board or schematic design.

A more detailed example layout of a circuit board is shown in FIG. 3. FIG. 3 depicts system 300 including an electronic circuit board design, in accordance with certain examples of the present disclosure. In particular, FIG. 3 shows an example physical arrangement of components populated on corresponding mounting features of circuit board 301. The components depicted in FIG. 3 may represent components populated on circuit board 301, or may instead represent the footprints or intended placements of components that can be populated onto an unpopulated circuit board 301. Also, while features of elements in FIG. 3 correspond numerically to electrical components of FIG. 1, it should be understood that other configurations of electrical components are possible

Circuit board 301 may include further extents than pictured, such as more components, target circuitry, and larger circuit board features with associated routing/planes. For example, ground plane 155 might span much of the circuit board surface or internal layers that are not designated for other components and voltage planes.

System 300 includes a first input routing structure, namely voltage input node Vin 1 141, and a second input routing structure, namely voltage input node Vin 2 142. Vin 1 141 and Vin 2 142 may collectively be referred to as an input voltage plane or rail. The voltage input nodes may receive a voltage input from a supply voltage input line (not shown). Example input voltages include 12 VDC, although other configurations are possible.

Vin 1 141 may couple to an input node for a voltage regulator controller or integrated circuit (VR1), represented via footprint 151. A voltage regulator may have a plurality of support components that can be populated onto circuit board 301 along with the voltage regulator controller. For example, voltage regulator 1 footprint 151 may be a footprint for a voltage regulator controller, while circuit board 301 may also include footprints for a variety of support components 160 for VR1, which will vary based on the exact controller selected. In some examples, VR1 and support components 160 may be collectively referred to as the voltage regulator or controller, and may be populated or unpopulated as a set. An example of VR1 151 may include a Richtech step-down converter RT6256CH, operating from 5.1V to 23V input voltage, with 750 kHz switching frequency. An example footprint for VR1 is shown at the bottom or FIG. 3. Support components 160 will be selected to suit the design needs of the selected VR1 component.

Vin 1 141 may also couple to a set of one or more input capacitors (CM 1), shown via footprints 147. The CM 1 147 may span from Vin 1 141 to the ground plane 155, and may be situated proximate to VR1 151 to reduce a current return path to within a threshold distance. Like the VR1 support components 160, the CM 1 147 may be populated or left unpopulated based on whether VR1 151 is or will be populated. An example set of CM 1 147 may include capacitors rated at 10 μF (microfarads), with 10% tolerance, 25V voltage rating, having a 0805 package size according to the JEDEC (Joint Electron Device Engineering Council) standards.

Vin 2 142 may couple to an input node for a voltage regulator 2 (VR2), shown via footprint 152. An example of VR2 152 may include a Monolithic Power Systems (MPS) step-down converter MP8771, operating from 3V to 18V input voltage, with 700 kHz switching frequency. An example footprint for VR2 is shown at the bottom or FIG. 3. Support components 162 will be selected to suit the design needs of the selected VR2 component.

Vin 2 142 may also couple to a set of one or more input capacitors (CM 2), shown via footprints 148, and spanning from Vin 2 142 to the ground plane 155. CM 2 148 may be situated proximate to the VR2 controller 152 to reduce a current return path to within a threshold distance. VR2 152 may have a different configuration and set of support components 162 and capacitors 148 than VR1 151. The VR2 support components 162 and CM 2 148 may be populated or left unpopulated based on whether VR2 152 is or will be populated on the circuit board. An example set of CM 2 148 may include capacitors rated at 10 uF, with 10% tolerance, 25V voltage rating, having a 0805 package size according to the JEDEC standards.

System 300 may include a switch node or switching node 145, which may comprise a routing plane or large metal routing formation. Switch node 145 may include a shared structure that couples to multiple voltage regulator footprints. For example, switch node 145 may couple to switch nodes of VR1 151 and VR2 152, with the switch nodes of the voltage regulators coupling to the shared switching node 145. The switch node 145 may also include a footprint for an inductor 154 (shown in FIG. 3 schematically superimposed on the footprint of inductor 154), and therefore may connect the switch nodes of any among the multiple voltage regulators to a first terminal of a shared inductor 154. An example inductor may be rated for 1.5 mH (microhenry) inductance, 12A maximum current, and 7.5 mOhm resistance. The specific inductor may be common to both VR1 and VR2, and thus may be populated regardless of the selected voltage regulator circuit which is populated. However, other examples may have a commonly used footprint, but a different specific inductor component that varies based on the selected population configuration.

System 300 includes a voltage output structure, such as a voltage output plane Vout 146. Vout 146 may include a conductive voltage plane or rail formed onto circuit board 301. Vout 146 may include a second terminal of the footprint of inductor 154, and may couple voltage received from the second terminal of the inductor to other components of a device via an output voltage node 158. Example output voltages include 5 VDC, although other configurations are possible.

Vout 146 may also include footprints for one or more output capacitors Cout, such as Cout 1 149 and Cout 2 150. Output capacitors may span from Vout 146 to ground plane 155. In some examples, the system 300 may include a set of output capacitor footprints corresponding to each voltage regulator footprint, such as Cout 1 149 corresponding to VR1 151, and Cout 2 150 corresponding to VR2 152. In another example, the number of sets of output capacitor footprints may differ from the number of voltage regulator footprints, with more or fewer output capacitor sets than voltage regulators. The output capacitor footprints may be situated proximate to footprints for the voltage regulators, so as to reduce current return paths to within a selected threshold distance. In the depicted example of FIG. 3, Cout 1 149 is situated proximate to VR1 151, while Cout 2 150 is situated proximate to VR2 152. In another example, footprints for a single set of output capacitors could be situated within a threshold distance of both VR1 151 and VR2 152, such as near output voltage node 158. An example set of Cout 1 149 may include one or more capacitors rated at 1 uF, 20% tolerance, 6.3V voltage rating, and having a 0201 package size, and one or more capacitors rated at 22 uF, with 20% tolerance, 6.3V voltage rating, and having a 0603 package size. An example set of Cout 2 150 may include one or more capacitors rated at 1 uF, 20% tolerance, 6.3V voltage rating, and having a 0201 package size, and one or more capacitors rated at 22 uF, with 20% tolerance, 6.3V voltage rating, and having a 0603 package size.

Although the embodiment of FIG. 3 shows all elements on a single side of a single circuit board, other arrangements are possible. For example, some components could be situated on a first side of a circuit board, and other components could be situated on a second side of the circuit board. Similarly, routes, planes, vias, and other elements could be distributed across different circuit board layers, where multiple circuit board layers may be arranged in a stack configuration and connected by way of corresponding vias.

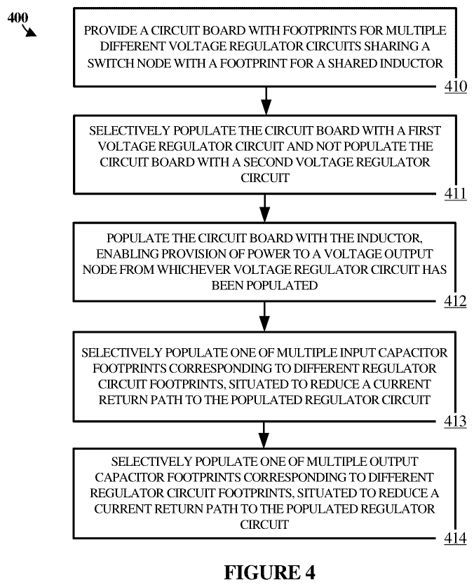

Turning now to FIG. 4, operations 400 illustrate a method of electronic circuit board design, in accordance with certain examples of the present disclosure. In particular, the operations of FIG. 4 may describe a method or process for manufacturing, designing, or assembling an electronic circuit board as described herein. The operations of FIG. 4 may be taken in a different order than described, depending on the actual manufacturing processes employed.

The method may include providing or generating a circuit board having footprints for multiple different voltage regulator circuits which can share a switch node with a footprint for a shared inductor, at operation 410. The term “footprint” as used herein is not limited to silk-screening or pre-drawn outlines for a component, but more generally to a space configured to receive a component and any support components, so that the component is fully functional when installed in a circuit board assembly. In the present example, the method may include providing a board with footprints for multiple voltage regulators having a different design, where any of the voltage regulators can connect to a shared inductor by way of a shared switch node voltage plane.

At operation 411, the method may include selectively populating the circuit board with a first voltage regulator circuit, and not populating the board with a second voltage regulator circuit. The circuit board may be configured to operate, and may be fully functional, with fewer than all of the voltage regulator footprints populated. Operation 412 then includes populating the circuit board with an inductor, enabling provision of power to a voltage output node of the circuit board from whichever voltage regulator circuit has been populated onto the board.

At operation 413, the method may include selectively populating one of multiple input capacitor footprints corresponding to different voltage regulator circuit footprints, based on which voltage regulator was populated. The populated input capacitors may be situated to reduce a current return path to the corresponding populated voltage regulator circuit. For example, a threshold distance between the input capacitors and the corresponding voltage regulator circuit may be selected to keep the current return path acceptably short. In some examples, multiple input capacitor footprints may be populated, regardless of which voltage regulator circuit or circuits have been selectively populated. In another example, a footprint for a single set of input capacitors may correspond to more than one voltage regulator circuit footprint.

At 414, the method may include selectively populating one of multiple output capacitor footprints corresponding to different voltage regulator circuit footprints, based on which voltage regulator was populated. As with the input capacitors, the populated output capacitors may be situated to reduce a current return path to the corresponding populated voltage regulator circuit. In some examples, multiple output capacitor footprints may be populated, regardless of which voltage regulator circuit or circuits have been selectively populated. In another example, a footprint for a single set of output capacitors may correspond to more than one voltage regulator circuit footprint.

Advantageously, the various examples described herein can provide for adaptable and supply-chain independent designs for circuit boards. This can be especially relevant when global conditions arise which disrupt component delivery to manufacturing sites, which ultimately delays the final assembly of associated devices. It should be understood that although two parallel power supply designs and layouts might be employed which share common components and nodes, more than two parallel designs and layouts can be employed. Also, although many of the included Figures show a shared inductor, this inductor might be representative of more than one inductive element, such as a single inductance value established using more than one physical inductor component in series. Similarly, capacitance values can be achieved using only a single capacitor component or multiple parallel capacitor components. Although the layouts and designs might be altered when employing more than one component in series or parallel, the associated concepts of circuit layout, design, and supply-chain flexibility are preserved.

The included enhancements provide several additional advantages. Specifically, the proposed new circuit board layouts and design of the voltage regulator circuitry offers a set of common components on a circuit board which work with the components from two or more component suppliers. This design requires no firmware modifications to switch from the components of one supplier to the other supplier. Due to occasional worldwide shortage of circuitry components, the use of components with unique footprints introduce supply risk to all products that utilize electronic circuits. The introduced solutions herein offer an agile circuit board layout which allows for population options among a set of designs to aid continuation of build and potentially reduce the costs from a Bill-of-Materials (BOM) perspective.

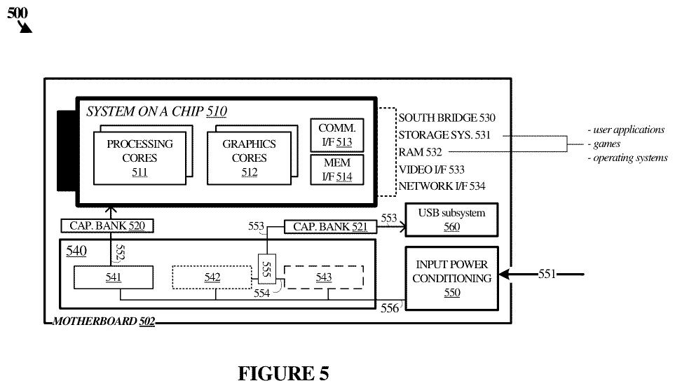

As an example environment into which the concepts and techniques discussed herein can be applied, FIG. 5 is presented. FIG. 5 illustrates computing system 500 that is representative of any system or collection of systems in which the various circuit board based operational architectures, platforms, scenarios, and processes disclosed herein may be implemented. For example, computing system 500 can be used to implement any of the circuit boards or the power supply or power regulator architectures discussed herein, such as system 100 of FIG. 1, system 200 of FIG. 2, system 300 of FIG. 3, and operations 400 of FIG. 4, among others.

Examples of computing system 500 include, but are not limited to, a gaming console, smartphone, tablet computer, laptop, server, personal communication device, personal assistance device, wireless communication device, subscriber equipment, customer equipment, access terminal, telephone, mobile wireless telephone, personal digital assistant, personal computer, e-book, mobile Internet appliance, wireless network interface card, media player, or some other computing apparatus, including combinations thereof.

Computing system 500 may be implemented as a single apparatus, system, or device or may be implemented in a distributed manner as multiple apparatuses, systems, or devices. Computing system 500 includes, but is not limited to, motherboard 502, system on a chip (SoC) device 510, and power system 540, and input power conditioning portion 550. Various contextual or peripheral elements can be included in computing system 500, such as mounted to motherboard 502 or included on separate circuit boards. These elements include south bridge 530, storage system 531, random-access memory (RAM) 532, video interfaces 533, and network interfaces 534. Furthermore, input power conditioning circuitry 550 and optional thermal management elements can be included. SoC device 510 can be optionally mounted to a carrier circuit board or package assembly mounted to motherboard 502.

SoC device 510 may comprise a microprocessor and processing circuitry that retrieves and executes software from storage system 531 and RAM 532. Software can include various operating systems, user applications, gaming applications, multimedia applications, or other user applications. SoC device 510 may be implemented within a single processing device, but may also be distributed across multiple processing devices or sub-systems that cooperate in executing program instructions. Examples of SoC device 510 include general purpose central processing units, application specific processors, graphics processing units, and logic devices, as well as any other type of processing device, combinations, or variations thereof. In FIG. 5, SoC device 510 includes processing cores 511, graphics cores 512, communication interfaces 513, memory interfaces 514, among other elements. Some of the noted elements of SoC device 510 can be included in a north bridge portion of SoC device 510. SoC device 510 is operatively coupled with other elements in computing system 500 external to SoC device 510, such as south bridge 530, storage system 531, RAM 532, video interfaces 533, and network interfaces 534.

Data storage elements of computing system 500 include storage system 531 and RAM 532. Storage system 531 and RAM 532 may comprise any computer readable storage media readable by SoC device 510 and capable of storing software. Storage system 531 and RAM 532 may include volatile and nonvolatile, removable and non-removable media implemented in any method or technology for storage of information, such as computer readable instructions, data structures, program modules, or other data. Examples of storage media include dynamic random access memory (DRAM), static random access memory (SRAM), read only memory, magnetic disks, optical disks, flash memory, virtual memory and non-virtual memory, magnetic disk storage or other magnetic storage devices, or any other suitable storage media. Storage system 531 may comprise additional elements, such as a controller, capable of communicating with SoC device 510 or possibly other systems.

South bridge 530 includes interfacing and communication elements which can provide for coupling of SoC device 510 to peripherals, user input devices, user interface devices, printers, microphones, speakers, or other external devices and elements. In some examples, south bridge 530 includes a system management bus (SMB) controller or other system management controller elements. Although south bridge 530 might include universal serial bus (USB) interface elements, these are shown as separate (560) in FIG. 5 for exemplary purposes.

Video interfaces 533 comprise various hardware and software elements for outputting digital images, video data, audio data, or other graphical and multimedia data which can be used to render images on a display, touchscreen, or other output devices. Digital conversion equipment, filtering circuitry, image or audio processing elements, or other equipment can be included in video interfaces 533.

Network interfaces 534 can provide communication between computing system 500 and other computing systems (not shown), which may occur over a communication network or networks and in accordance with various communication protocols, combinations of protocols, or variations thereof. Example networks include intranets, internets, the Internet, local area networks, wide area networks, wireless networks, wired networks, virtual networks, software defined networks, data center buses, computing backplanes, or any other type of network, combination of network, or variation thereof. The aforementioned communication networks and protocols are well known and need not be discussed at length here. However, some communication protocols that may be used include, but are not limited to, the Internet protocol (IP, IPv4, IPv6, etc.), the transmission control protocol (TCP), and the user datagram protocol (UDP), as well as any other suitable communication protocol, variation, or combination thereof.

Computing system 500 can also comprise one or more enclosures that can include various structural support elements, cases, chassis elements, or other elements that house and structurally support the further elements of computing system 500. Optional thermal management elements can include heatsinks, fans, heat pipes, heat pumps, refrigeration elements, or other elements to manage and control temperature of an optional enclosure and computing system 500. Typically, thermal management elements are included for SoC device 510 or associated circuitry, along with thermal monitoring elements.

Input power conditioning 550 can include filtering, surge protection, electromagnetic interference (EMI) protection and filtering, as well as perform other input power functions for input power 551. In some examples, input power conditioning 550 includes AC-DC conversion circuitry, such as transformers, rectifiers, power factor correction circuitry, or switching converters. When a battery source is employed as input power 551, then input power conditioning 550 can include various diode protection, DC-DC conversion circuitry, or battery charging and monitoring circuitry. Some of the elements of power system 540 might be included in input power conditioning 550.

SoC device 510 includes many different internal elements and structures, such as processing cores 511, graphics cores 512, communication interfaces 513, and memory interfaces 514. Each of these internal elements might be associated with a separate or dedicated voltage domain, or one or more of these internal elements might be serviced by multiple voltage domains. A voltage domain can comprise a set of power links, planes, distribution structures, or interconnect which is independent within SoC device 510 from other voltage domains. Power distribution structures of each voltage domain can receive input voltages having different voltage levels, which may be independently varied. For example, processing cores 511 might all prefer a different nominal input voltage level (VDD).

Power system 540 includes a plurality of voltage regulator units 541-543. Power system 540 receives supply power over link 556 from input power conditioning circuitry 550. Link 556 can represent more than one voltage link or power link, although in this example 12 VDC is employed as an exemplary voltage level. Internal power distribution links can deliver power received via power link 556 to individual voltage regulator units 541-543. Voltage regulator units 541-543 individually alter voltage levels to produce input power for delivery to individual voltage domains of SoC device 510 or to various peripheral components, such as USB subsystem 560. SoC device 510 receives power over input power link 552 as supplied by at least one of the plurality of voltage regulator units 541-543. USB subsystem 560 receives power over input power link 553, as supplied by at least one of the plurality of voltage regulator units 541-543. Power links 552-553 can also be referred to as power domains, power rails, voltage rails, or power planes.

Voltage regulator units 541-543 can provide supply voltages at associated current levels to associated target devices. In many examples, voltage adjustment units can convert or alter a supply voltage of link 556 to a different output voltage on associated links 552-553, along with any related voltage regulation. Voltage regulator units 541-543 might receive supply power over link 556 at a first voltage level and convert this first voltage level into second voltage levels. These second voltage levels can be different among each of voltage regulator units 541-543, and each can correspond to a different voltage domain or voltage rail. Voltage regulator units 541-543 comprise various power electronics, power controllers, DC-DC conversion circuitry, power transistor gate modulation circuitry, power transistors, half-bridge elements, filters, passive components, and other elements to convert supply power received over link 556 into power usable by target devices.

Output capacitors 520-521 for voltage regulator units 541-543 is included in computing device 500. Each of capacitor banks 520-521 includes a plurality of individual or discrete capacitors coupled to motherboard 502. Capacitor banks 520-521 can be examples of output capacitors 149-150 of FIG. 1. Individual capacitors of capacitor banks 520-521 are coupled between an associated voltage link and a reference potential for that voltage link.

Voltage regulator units 542-543 are shown in a particular configuration which includes populating components of only one of voltage regulator units 542-543 at a time. Thus, components of either voltage regulator unit 542 or unit 543 would be populated on the corresponding motherboard 502. Inductor 555 is shared among voltage regulator units 542-543, and is populated regardless of the population status of voltage regulator units 542-543. A shared output voltage link 553 is shown as sharing a common capacitor bank 521, although variations are possible, such as having separately populated capacitor banks each corresponding to a particular voltage regulator unit. Switch node 554 is also shared among voltage regulator units 542-543, which couples to a first terminal of inductor 555. A second terminal of inductor 555 is coupled to voltage link 553. In this example, voltage link 553 provides+5 VDC to USB subsystem 560. However, similar architectures as voltage regulator units 542-543 can be employed for voltage link 552 that provides power to one or more of the cores of SoC 510.

Certain inventive aspects may be appreciated from the foregoing disclosure, of which the following are various examples.

Example 1: An apparatus comprising an input structure on a circuit board that couples an input voltage node to input nodes of more than one voltage regulator circuit, wherein at least controller footprints differ among each of the more than one voltage regulator circuit. The apparatus includes a shared structure that couples switch nodes of the more than one voltage regulator circuit to a first terminal of an inductor footprint common to the more than one voltage regulator circuit. The apparatus includes an output structure that couples a second terminal of the inductor footprint to an output voltage node.

Example 2: The apparatus of Example 1 comprising a circuit board assembly comprising the circuit board populated with components unique to a first voltage regulator circuit and not including components unique to a second voltage regulator circuit, wherein the circuit board assembly is configured to provide power to the output voltage node using an inductor populated into the inductor footprint common to the more than one voltage regulator circuit.

Example 3: The apparatus of Examples 1-2 comprising the input structure having a first set of footprints for a first set of input capacitors placed proximate to a controller for a first of the more than one voltage regulator circuit, and a second set of footprints for a second set of input capacitors placed proximate to a controller for a second of the more than one voltage regulator circuit.

Example 4: The apparatus of Examples 1-3 comprising the first set of footprints and the second set of footprints are situated to reduce current return paths, to the respective controllers for the first and second of the one or more voltage regulator circuit, to threshold distances.

Example 5: The apparatus of Examples 1˜4 comprising the output structure having a third set of footprints for a set of output capacitors placed proximate to both the controller for the first of the more than one voltage regulator circuit and the controller for the second of the more than one voltage regulator circuit.

Example 6: The apparatus of Examples 1-5 comprising the output structure having a first set of footprints for a first set of output capacitors placed proximate to a controller for a first of the more than one voltage regulator circuit, and a second set of footprints for a second set of output capacitors placed proximate to a controller for a second of the more than one voltage regulator circuit.

Example 7: The apparatus of Examples 1-6 comprising the first set of footprints and the second set of footprints are situated to reduce current return paths, to the respective controllers for the first and second of the one or more voltage regulator circuit, to threshold distances.

Example 8: The apparatus of Examples 1-7 comprising the input structure having a third set of footprints for a first set of input capacitors placed proximate to the controller for the first of the more than one voltage regulator circuit, and a fourth set of footprints for a second set of input capacitors placed proximate to the controller for the second of the more than one voltage regulator circuit, wherein the third set of footprints and the fourth set of footprints are situated to reduce current return paths, to the respective controllers for the first and second of the one or more voltage regulator circuit, to threshold distances.

Example 9: The apparatus of Examples 1-8, wherein components of only one among the more than one voltage regulator circuit is populated at any one time.

Example 10: A system comprising a circuit board, and an input structure on the circuit board that couples an input voltage node to input nodes of more than one voltage regulator circuit, wherein at least controller footprints differ among each of the more than one voltage regulator circuit. The system includes components unique to a first voltage regulator circuit populated onto first footprints of the circuit board, and components unique to a second voltage regulator circuit not populated onto second footprints of the circuit board. The system includes an input structure on the circuit board that couples an input voltage node to input nodes of the first voltage regulator circuit and the second voltage regulator circuit. The system includes a shared structure on the circuit board that couples switch nodes of the first and the second voltage regulator circuits to a first terminal of an inductor, such that the inductor is common to the more than one voltage regulator circuit. The system includes an output structure on the circuit board that couples a second terminal of the inductor to an output voltage node, wherein the output structure is configured to provide power to the output voltage node through the inductor when either one of the components unique to the first voltage regulator circuit and components unique to the second voltage regulator circuit are populated onto the circuit board.

Example 11: The system of Example 10 comprising the input structure having a first set of footprints for a first set of input capacitors placed proximate to a controller for the first voltage regulator circuit, a second set of footprints for a second set of input capacitors placed proximate to a controller for the second voltage regulator circuit, wherein the first set of input capacitors are populated corresponding to the populated components unique to the first voltage regulator circuit, and the second set of input capacitors are not populated.

Example 12: The system of Examples 10-11 comprising the first set of footprints for the first set of input capacitors and the second set of footprints for the second set of input capacitors are situated to reduce current return paths, to the respective controllers for the first voltage regulator circuit and the second voltage regulator circuit, to threshold distances.

Example 13: The system of Examples 10-12 comprising the output structure having a set of output capacitors situated to reduce current return paths to both the controller for the first voltage regulator circuit and the controller for the second voltage regulator circuit.

Example 14: The system of Examples 10-13 comprising the output structure having a first set of footprints for a first set of output capacitors situated to reduce a current return path to a controller for the first voltage regulator circuit to a threshold distance, a second set of footprints for a second set of output capacitors situated to reduce a current return path to a controller for the second voltage regulator circuit to the threshold distance. The first set of output capacitors are populated corresponding to the populated components unique to the first voltage regulator circuit, and the second set of output capacitors are not populated.

Example 15: The system of Examples 10-14, wherein components of only one among the more than one voltage regulator circuit is populated at any one time.

Example 16: A method comprising forming an input structure on a circuit board that couples an input voltage node to input nodes of a first voltage regulator circuit and a second voltage regulator circuit, wherein at least controller footprints differ among the first and the second voltage regulator circuits. Forming a shared structure on the circuit board that couples switch nodes of the first and the second voltage regulator circuits to a first terminal of an inductor footprint common to the first and the second voltage regulator circuits. Forming an output structure on the circuit board that couples a second terminal of the inductor footprint to an output voltage node. Selectively populating the circuit board with either components unique to the first voltage regulator circuit or components unique to the second voltage regulator circuit. Populating the circuit board with the inductor, wherein the provision of power to the voltage output node is enabled by way of the selectively populated first voltage regulator circuit or second voltage regulator circuit.

Example 17: The method of Example 16 comprising selectively populating the circuit board with either the components unique to the first voltage regulator circuit or the components unique to the second voltage regulator circuit based on availability during manufacturing among the components unique to the first voltage regulator circuit or the components unique to the second voltage regulator circuit.

Example 18: The method of Examples 16-17 comprising forming the input structure as including a first set of footprints for a first set of input capacitors situated to reduce a current return path to a controller for the first voltage regulator circuit, and a second set of footprints for a second set of input capacitors situated to reduce a current return path to a controller for the second voltage regulator circuit. Selectively populating either the first set of input capacitors or the second set of input capacitors, selected based on the populated first voltage regulator circuit or second voltage regulator circuit.

Example 19: The method of Examples 16-18 comprising populating the output structure with a set of output capacitors situated to reduce a current return path to a controller for the selectively populated first voltage regulator circuit or second voltage regulator circuit.

Example 20: The method of Examples 16-19 comprising forming the output structure as including a first set of footprints for a first set of output capacitors situated to reduce a current return path to a controller for the first voltage regulator circuit, and a second set of footprints for a second set of input capacitors situated to reduce a current return path to a controller for the second voltage regulator circuit. Selectively populating either the first set of output capacitors or the second set of output capacitors, selected based on the populated first voltage regulator circuit or second voltage regulator circuit.

The functional block diagrams, operational scenarios and sequences, and flow diagrams provided in the Figures are representative of exemplary systems, environments, and methodologies for performing novel aspects of the disclosure. The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the invention. Those skilled in the art will also appreciate that the features described above can be combined in various ways to form multiple implementations. As a result, the invention is not limited to the specific implementations described above, but only by the claims and their equivalents.

What is claimed is:

1. An apparatus comprising:
an input structure on a circuit board that couples an input voltage node to input nodes of more than one voltage regulator circuit, wherein at least controller footprints differ among each of the more than one voltage regulator circuit;
a shared structure that couples switch nodes of the more than one voltage regulator circuit to a first terminal of an inductor footprint common to the more than one voltage regulator circuit; and
an output structure that couples a second terminal of the inductor footprint to an output voltage node.

2. The apparatus of claim 1 comprising:
a circuit board assembly comprising the circuit board populated with components unique to a first voltage regulator circuit and not including components unique to a second voltage regulator circuit; and
wherein the circuit board assembly is configured to provide power to the output voltage node using an inductor populated into the inductor footprint common to the more than one voltage regulator circuit.

3. The apparatus of claim 1 comprising:
the input structure comprising:
a first set of footprints for a first set of input capacitors placed proximate to a controller for a first of the more than one voltage regulator circuit; and
a second set of footprints for a second set of input capacitors placed proximate to a controller for a second of the more than one voltage regulator circuit.

4. The apparatus of claim 3 comprising:
the first set of footprints and the second set of footprints situated to reduce current return paths, to the respective controllers for the first and second of the one or more voltage regulator circuit, to threshold distances.

5. The apparatus of claim 3 comprising:
the output structure comprising a third set of footprints for a set of output capacitors placed proximate to both the controller for the first of the more than one voltage regulator circuit and the controller for the second of the more than one voltage regulator circuit.

6. The apparatus of claim 1 comprising:
the output structure comprising:
a first set of footprints for a first set of output capacitors placed proximate to a controller for a first of the more than one voltage regulator circuit; and
a second set of footprints for a second set of output capacitors placed proximate to a controller for a second of the more than one voltage regulator circuit.

7. The apparatus of claim 6 comprising:
the first set of footprints and the second set of footprints situated to reduce current return paths, to the respective controllers for the first and second of the one or more voltage regulator circuit, to threshold distances.

8. The apparatus of claim 6 comprising:
the input structure comprising:
a third set of footprints for a first set of input capacitors placed proximate to the controller for the first of the more than one voltage regulator circuit; and
a fourth set of footprints for a second set of input capacitors placed proximate to the controller for the second of the more than one voltage regulator circuit
wherein the third set of footprints and the fourth set of footprints are situated to reduce current return paths, to the respective controllers for the first and second of the one or more voltage regulator circuit, to threshold distances.

9. The apparatus of claim 1, wherein components of only one among the more than one voltage regulator circuit is populated at any one time.

10. A system comprising:
a circuit board;
an input structure on the circuit board that couples an input voltage node to input nodes of more than one voltage regulator circuit, wherein at least controller footprints differ among each of the more than one voltage regulator circuit;
components unique to a first voltage regulator circuit populated onto first footprints of the circuit board;
components unique to a second voltage regulator circuit not populated onto second footprints of the circuit board;
an input structure on the circuit board that couples an input voltage node to input nodes of the first voltage regulator circuit and the second voltage regulator circuit;
a shared structure on the circuit board that couples switch nodes of the first and the second voltage regulator circuits to a first terminal of an inductor, such that the inductor is common to the more than one voltage regulator circuit; and
an output structure on the circuit board that couples a second terminal of the inductor to an output voltage node, wherein the output structure is configured to provide power to the output voltage node through the inductor when either one of the components unique to the first voltage regulator circuit and components unique to the second voltage regulator circuit are populated onto the circuit board.

11. The system of claim 10 comprising:
the input structure comprising:
a first set of footprints for a first set of input capacitors placed proximate to a controller for the first voltage regulator circuit;
a second set of footprints for a second set of input capacitors placed proximate to a controller for the second voltage regulator circuit;
the first set of input capacitors populated corresponding to the populated components unique to the first voltage regulator circuit; and
the second set of input capacitors not populated.

12. The system of claim 11 comprising:
the first set of footprints for the first set of input capacitors and the second set of footprints for the second set of input capacitors are situated to reduce current return paths, to the respective controllers for the first voltage regulator circuit and the second voltage regulator circuit, to threshold distances.

13. The system of claim 12 comprising:
the output structure comprising a set of output capacitors situated to reduce current return paths to both the controller for the first voltage regulator circuit and the controller for the second voltage regulator circuit.

14. The system of claim 12 comprising:
the output structure comprising:
a first set of footprints for a first set of output capacitors situated to reduce a current return path to a controller for the first voltage regulator circuit to a threshold distance;
a second set of footprints for a second set of output capacitors situated to reduce a current return path to a controller for the second voltage regulator circuit to the threshold distance; and
the first set of output capacitors populated corresponding to the populated components unique to the first voltage regulator circuit; and
the second set of output capacitors not populated.

15. The system of claim 11, wherein components of only one among the more than one voltage regulator circuit is populated at any one time.

16. A method comprising:
forming an input structure on a circuit board that couples an input voltage node to input nodes of a first voltage regulator circuit and a second voltage regulator circuit, wherein at least controller footprints differ among the first and the second voltage regulator circuits;
forming a shared structure on the circuit board that couples switch nodes of the first and the second voltage regulator circuits to a first terminal of an inductor footprint common to the first and the second voltage regulator circuits;
forming an output structure on the circuit board that couples a second terminal of the inductor footprint to an output voltage node;
selectively populating the circuit board with either components unique to the first voltage regulator circuit or components unique to the second voltage regulator circuit; and
populating the circuit board with the inductor, wherein the provision of power to the voltage output node is enabled by way of the selectively populated first voltage regulator circuit or second voltage regulator circuit.

17. The method of claim 16 comprising:
selectively populating the circuit board with either the components unique to the first voltage regulator circuit or the components unique to the second voltage regulator circuit based on availability during manufacturing among the components unique to the first voltage regulator circuit or the components unique to the second voltage regulator circuit.

18. The method of claim 16 comprising:
forming the input structure as including:
a first set of footprints for a first set of input capacitors situated to reduce a current return path to a controller for the first voltage regulator circuit; and
a second set of footprints for a second set of input capacitors situated to reduce a current return path to a controller for the second voltage regulator circuit; and
selectively populating either the first set of input capacitors or the second set of input capacitors, selected based on the populated first voltage regulator circuit or second voltage regulator circuit.

19. The method of claim 18 comprising:
populating the output structure with a set of output capacitors situated to reduce a current return path to a controller for the selectively populated first voltage regulator circuit or second voltage regulator circuit.

20. The method of claim 19 comprising:
forming the output structure as including:
a first set of footprints for a first set of output capacitors situated to reduce a current return path to a controller for the first voltage regulator circuit; and
a second set of footprints for a second set of input capacitors situated to reduce a current return path to a controller for the second voltage regulator circuit; and
selectively populating either the first set of output capacitors or the second set of output capacitors, selected based on the populated first voltage regulator circuit or second voltage regulator circuit.
